(19) United States
(12) Patent Application Publication
(10) Pub. No.: US 2008/0030965 A1
(43) Pub. Date: Feb. 7, 2008

(54) Circuit board structure with capacitors embedded therein and method for fabricating the same

(75) Inventors: Chung-Cheng Lien, Hsin-feng (TW); Chih-Kui Yang, Hsin-feng (TW)

Correspondence Address: BACON & THOMAS, PLLC, 625 SLATERS LANE, FOURTH FLOOR, ALEXANDRIA, VA, 22314, US

(73) Assignee: Phoenix Precision Technology Corporation, Hsinchu (TW)

(21) Appl. No.: 11/701,441

(22) Filed: Feb. 2, 2007

(30) Foreign Application Priority Data
Aug. 4, 2006 (TW) 095128674

(51) Int. Cl. H05K 1/00

(52) U.S. Cl. 361/748; 29/830

(57) ABSTRACT

A circuit board structure with capacitor embedded therein and method for fabricating the same are disclosed, especially a core structure with capacitors embedded therein and method for fabricating the same. The structure comprising: a core board having a dielectric layer with a first surface and an opposite second surface; at least one high dielectric coefficient material layer formed in the dielectric layer, wherein a first electrode plate formed on the other surface of the high dielectric coefficient material layer; a first circuit layer formed on the first surface of the dielectric layer; a second circuit layer formed on the second surface of the dielectric layer and having a second electrode plate corresponding to the first electrode plate; and a first conductive via formed in the dielectric layer and electrically connecting the first electrode plate and the first circuit layer.

### BACKGROUND OF THE INVENTION

1. Field of the Invention

The present invention relates to a circuit board having capacitors embedded therein and fabricating method thereof and, more particularly, to a core board structure having capacitors embedded therein and fabricating method thereof. Through the above-mentioned structure and fabricating method, the flexibility of circuit layout on/in the circuit board is increased.

2. Description of Related Art

Currently, the relentless progress in semiconductor fabricating process and electronic functions of microelectronic devices has lead to a highly integrated development of semiconductor chips. Quantity of pins and density of wiring in package structures increase as semiconductor chips develop toward to high integration. However, as the density of wiring in a package structure increase, the noise signals also increase. Generally, in order to obviate noise signals or compensate electricity, passive components, e.g. resistors, capacitors, and inductors, are installed in semiconductor package structures to eliminate noise signals and to stabilize circuits to thereby meet the requirements of microelectronic devices.

In conventional methods, utilizing surface mount technology (SMT) integrates most passive components onto a surface of a packaging substrate, such that the flexibility of wiring layout on the surface is restricted, and the shrinkage of package size is unfavorable.

In view of the aforementioned drawbacks, many studies relative to lamination methods have appeared in recent years. High dielectric coefficient material is laminated into copper layers and then electrode plates and circuits are formed to fabricate capacitors. FIG. 1c shows a perspective view of a circuit board structure laminated with capacitors. As shown in FIG. 1a, the fabricating method is providing a metal layer 10, whereon a high dielectric coefficient material layer 11, another metal layer 12, and a dielectric layer 13 are formed in sequence, to thereby make a carrier board 1 having capacitors embedded therein. Then with reference to FIG. 1b, providing a core board 2 having a dielectric layer 20 with a circuit layer 21 formed on each of the opposite two surfaces thereof, wherein the carrier boards 1 are corresponding to and laminated with the opposite two surfaces of the core board 2 to thereby form a pre-circuit board structure. Afterwards, the pre-circuit board structure undergoes drilling for through holes (not shown) or laser ablation for via holes, followed by forming patterned circuit layers 101 from the metal layers 10 on the opposite two surfaces of the pre-circuit board structure, as well as forming conductive vias 102 therein; thus a circuit board structure having capacitors embedded therein as shown in FIG. 1c is completed. The disadvantage of the above-described structure is the difficulty in alignment between the carrier board and the core board during the lamination process. Hence, tooling holes have to be formed by drilling a panel, and are aligned with pins, e.g. four pins relative to opposite four tooling holes. However, alignment errors may occur not only during drilling, but also during lamination. Therefore, although better than conventional methods, SMT, the above-mentioned method still has difficulty of alignment, and it results in decrease of the production yield. Moreover, fabrication of the above-mentioned method is more complex such that the production cost is increased.

Another disadvantage of the above-described structure is that the electrode plates and the circuit are formed from the same metal layer, so the flexibility of the circuit layout is compromised.

Therefore, it is desirable to provide an improved circuit board structure having capacitors embedded therein and fabricating method thereof to mitigate and/or obviate the aforementioned drawbacks.

### SUMMARY OF THE INVENTION

In view of the above prior art disadvantages, the object of the present invention is to provide a circuit board having capacitors embedded therein and fabricating method thereof, whereby advanced flexibility of circuit layout on the circuit board is achieved.

Another object of the present invention is to provide a circuit board having capacitors embedded therein and fabricating method thereof, so as to avoid alignment errors occurring during drilling and lamination. Therefore, quality of products is advanced, and fabricating method is simplified to decrease the production cost.

To achieve the above objects, a circuit board having capacitors embedded therein in the present invention includes: a core board having a dielectric layer with a first surface and an opposite second surface; at least one high dielectric coefficient material layer formed in the dielectric layer and having one surface at the same height as the second surface of the dielectric layer, wherein a first electrode plate formed on the other surface of the high dielectric coefficient material layer; a first circuit layer formed on the first surface of the dielectric layer; a second circuit layer formed on the second surface of the dielectric layer and having a second electrode plate corresponding to the first electrode plate; and a first conductive via formed in the dielectric layer and electrically connecting the first electrode plate and the first circuit layer.

In the above structure, the second circuit layer further comprises a conductive wire electrically connecting to the second electrode plate.

In addition, the above structure further comprises at least one second conductive via or at least one conductive through hole formed in the dielectric layer and electrically connecting the first circuit layer and the second circuit layer.

The present invention also discloses a method of fabricating a circuit board having capacitors embedded therein contains the following steps: providing a carrier board having at least one high dielectric coefficient material layer formed on a part of one surface of the carrier board, and forming a first electrode plate on the surface of the high dielectric coefficient material layer; forming a dielectric layer on the surface of the carrier board with the first electrode plate formed thereon; forming a first via hole corresponding to the first electrode plate in the dielectric layer; forming a first circuit layer on the first surface of the dielectric layer and a first conductive via in the first via hole; and forming a second circuit layer on the second surface of the dielectric layer and at least a second electrode plate within the second circuit layer corresponding to the first electrode plate.

In the above method, the second circuit layer further comprises a conductive wire electrically connecting to the second electrode plate, wherein the first conductive via electrically connects the first circuit layer and the first electrode plate.

The above method further comprises forming at least one second conductive via or at least one conductive through hole in the dielectric layer, wherein the second conductive via or the conductive through hole electrically connects the first circuit layer and the second circuit layer.

The present invention discloses a core board structure having capacitors embedded therein and fabricating method thereof further comprise forming a built-up structure on each of the two sides of the circuit board, so as to complete a multilayer circuit board, to thereby be applied to the flip-chip or wire-bonding semiconductor packaging substrates in order to improve the flexibility of circuit layout.

Moreover, in the present invention, the circuit board having capacitors embedded therein and fabricating method thereof can avoids alignment errors during drilling and lamination in the conventional method. Therefore, quality of products is advanced, and fabricating method is simplified to decrease the production cost.

Other objects, advantages, and novel features of the invention will become more apparent from the following detailed description when taken in conjunction with the accompanying drawings.

### BRIEF DESCRIPTION OF THE DRAWINGS

FIGS. 1a to 1c show a perspective view of the conventional fabricating method for lamination capacitors on a circuit board structure.

FIGS. 2a to 2f′ show a perspective view of the method in fabricating embodiment 1 of a circuit board structure having capacitors embedded therein in the present invention.

FIGS. 3a to 3f′ show a perspective view of the method in fabricating embodiment 2 of a circuit board structure having capacitors embedded therein in the present invention.

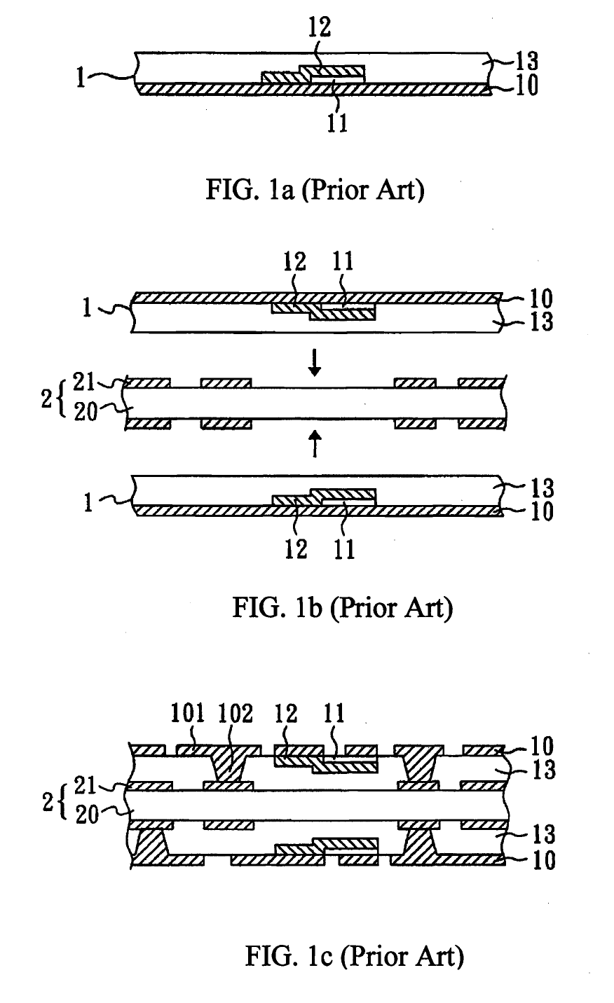

### DETAILED DESCRIPTION OF THE PREFERRED EMBODIMENT

Because of the specific embodiments illustrating the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

The drawings of the embodiments in the present invention are all simplified charts, and only reveal elements relative to the present invention. The elements revealed in the drawings are not aspects of the practice, and quantity and shape thereof are optionally designed. Further, the design aspect of the elements can be more complex.

### Fabricating Embodiment 1

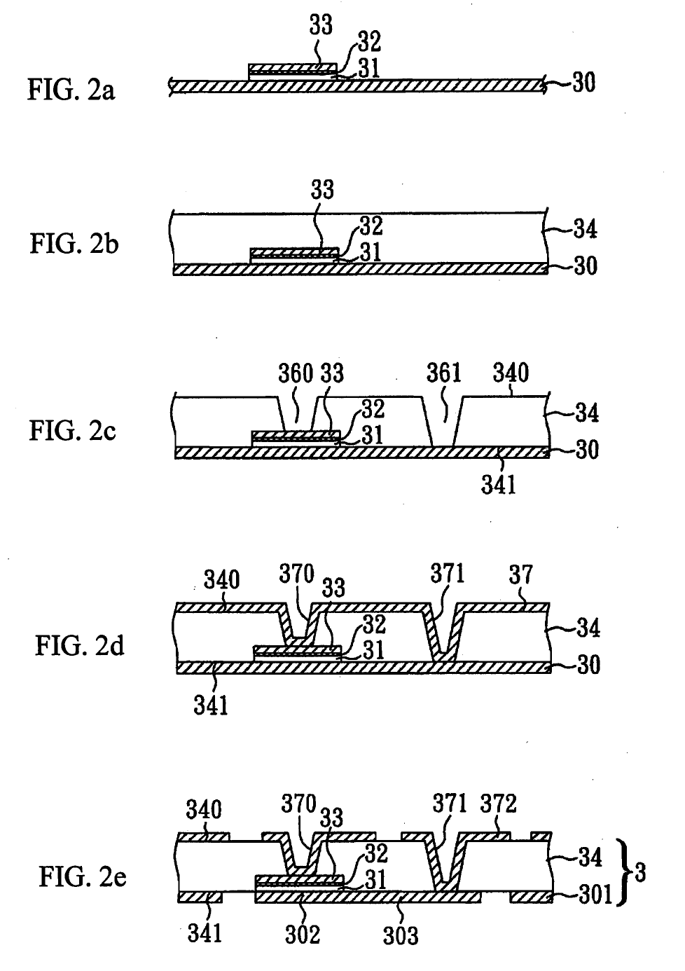

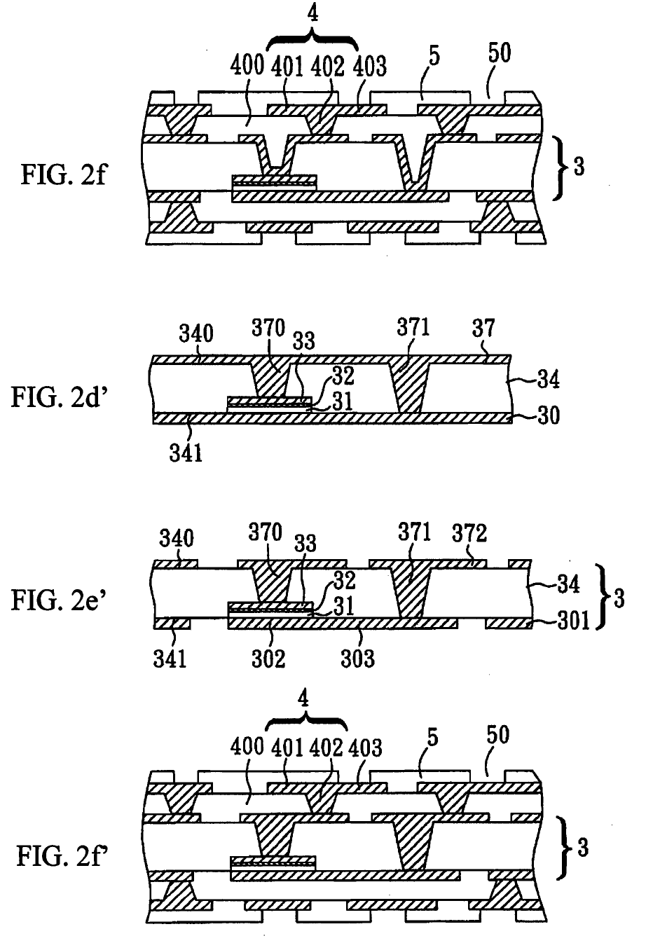

With reference to FIG. 2a, first a carrier board 30, which can be a metal plate, is provided. A high dielectric coefficient material layer 31, of which the dielectric coefficient ranges from 40 to 4000, is formed through any way of sputtering, coating, or printing on a part of the surface of the carrier board 30. The high dielectric coefficient material is polymeric material, ceramic material, polymeric material filled with ceramic material, or mixture of the like thereof. In other words, it could be any one of the groups consisting of barium-tianate, lead-zirconate-tianate, and amorphous hydrogenated carbon, formed by dispersing to a binder. Subsequently, an pre-electrode layer 32, of which material is either copper paste or silver paste, is formed by any way of sputtering, coating, or printing on the surface of the high dielectric coefficient material layer 31. Then, through high temperature sintering, the high dielectric coefficient material layer 31 and the pre-electrode layer 32 are condensed.

However, because the pre-electrode layer 32 is condensed through high temperature sintering, the thickness thereof is not sufficient. Therefore, after sintering, an thickness-increasing layer is formed by any way of electroplating, physical deposition, e.g. sputtering, and evaporation, and chemical deposition, e.g. electroless plating, on the surface of the pre-electrode layer 32, to thereby serve as a first electrode plate 33. The thickness-increasing layer is made of one of the group consisting of copper, tin, nickel, chromium, titanium, copper-chromium alloy, and tin-lead alloy.

As shown in FIG. 2b, a dielectric layer 34 is formed on the surface of the carrier board 30 having the first electrode plate 33. The dielectric layer is selected from one of the group consisting of Ajinomoto Build-up Film (ABF)™, benzocyclo-butene (BCB), liquid crystal polymer (LCP), poly-imide (PI), poly(phenylene ether) (PPE), poly(tetra-fluoroethylene) (PTFE), FR4, FR5, bismaleimide triazine (BT), aramide, which are photosensitive or non-photosensitive organic resin, and a mixture of epoxy resin or fiber glass combined with them.

Subsequently, as shown in FIG. 2c, a first via hole 360 and a second via hole 361 are formed by laser ablation, wherein the first via hole 360 corresponds to the first electrode plate 33, and the second via hole 361 extends through the dielectric layer 34.

Further, as shown in FIGS. 2d and 2d′, a seed layer (not shown in the figures) is formed by electroless plating on the first surface 340 of the dielectric layer 34, as well as on the walls of the first via hole 360 and the second via hole 361. The seed layer is a pathway for conducting current and required for a following electro-plating process to thereby form a metal layer 37, a first conductive via 370, and a second conductive via 371. Herein, the difference between FIG. 2d and FIG. 2d′ is that the first conductive via 370 and the second conductive via 371 in FIG. 2d′ are filled with metal, but those in FIG. 2d are not.

Finally, in FIGS. 2e and 2e′, by etching the metal layer 37 and the carrier board 30, a first circuit layer 372 and a second circuit layer 301 are formed on the two opposite surfaces of the dielectric layer 34, wherein the second circuit layer 301 has a second electrode plate 302 corresponding to the first electrode plate 33. Hence, the first electrode plate 33, the second electrode plate 302, and the high dielectric coefficient material layer therein serve as a capacitor structure, and then the structure of a core board 3 having capacitors embedded therein is completed. Further, the thickness of the carrier board 30 can be decreased before forming the circuit.

The aforementioned method further comprises another way of forming the first circuit layer 372 and the second circuit layer 301 by electro-plating. With reference to FIG. 2c, the carrier board 30 is removed (not shown in the figure) to expose the second surface 341 of the dielectric layer 34. A seed layer (not shown in the figure) is formed by electroless plating on the first surface 340, the second surface 341, and the walls of the first via hole 360 and the second via hole 361 in the dielectric layer 34. After forming a patterned resistive layer (not shown in the figure) on the seed layer, a patterned first circuit layer 372, a second circuit layer 301, a first conductive via 370, and a second conductive via 371 are formed as shown in FIGS. 2e and 2e′. The structure of a core board 3 having capacitors embedded therein is completed.

Furthermore, as shown in FIGS. 2f and 2f′, a built-up structure 4 is formed on each of the two opposite surfaces of the core board 3 through build-up technology. The built-up structure 4 has at least one dielectric layer 400, at least one circuit layer 401, a plurality of conductive vias 402, and a plurality of connecting pads 403. A solder mask layer 5 having a plurality of openings 50 to expose the connecting pad 403 is formed on the surface of the built-up structure 4.

In the aforementioned method, the dielectric layer 34 also can be a dielectric layer having a thin metal layer on the surface thereof (not shown in the figure), for example, resin coated copper foil (RCC).

### Fabricating Embodiment 2

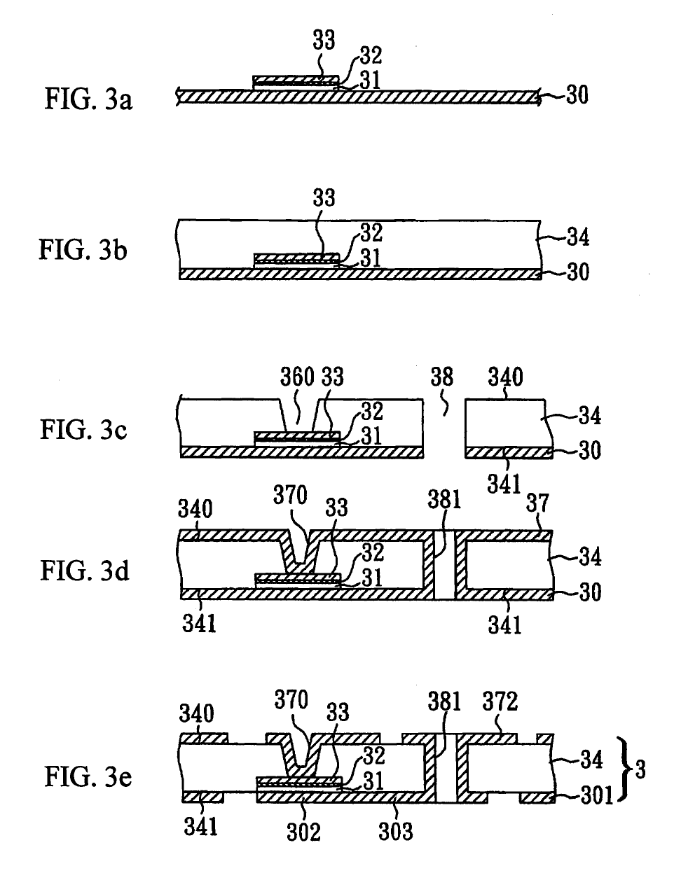

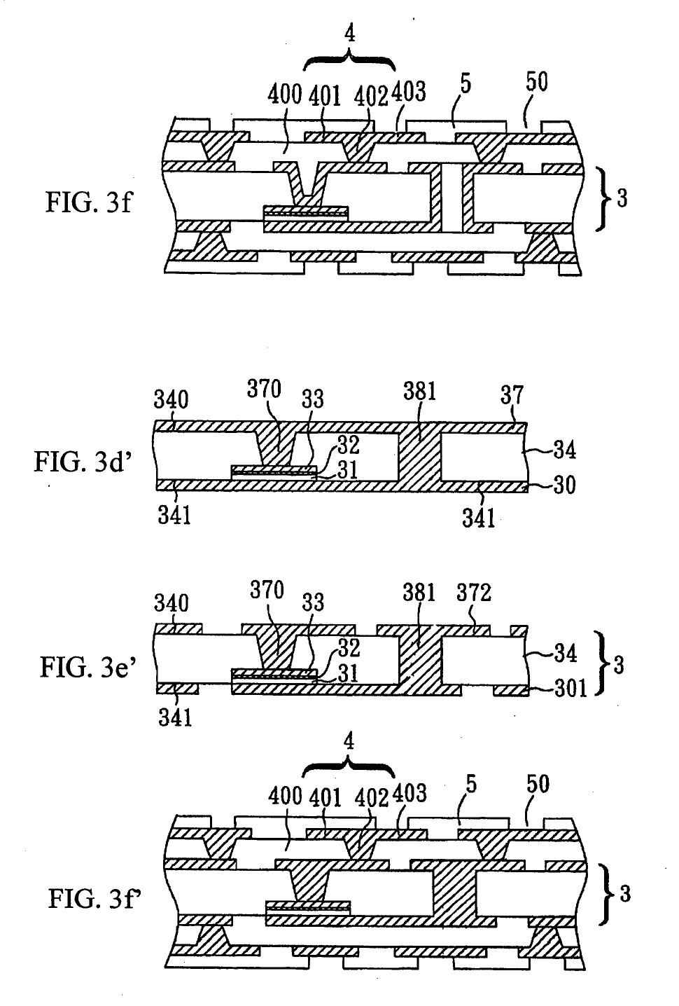

As shown from FIGS. 3a to 3f, the fabricating method of the embodiment 2 in the present invention is approximately similar to the method of the embodiment 1, but the difference is that forming a conductive through-hole 381, replacing a second conductive via in the structure of the present invention.

With reference to FIGS. 3c to 3f, the difference from the embodiment 1 is to form a through-hole 38 by mechanical drilling, followed by forming a conductive through-hole 381, electrically connecting the first circuit layer 372 and the second circuit layer 301. The method of forming the conductive through-hole 381 is well known in the art and thus further description is not necessary. Herein, the difference between FIGS. 3d to 3f and FIGS. 3d′ to 3f′ is that the first conductive via 370 and the conductive through-hole 381 in FIGS. 3d′ to 3f′ are filled with metal, but those in FIGS. 3d to 3f are not.

### Structural Embodiment

The present invention further provides a circuit board structure having capacitors embedded therein, and particularly a core board structure having capacitors embedded therein. With reference to FIGS. 2e, 2e′, 3e, and 3e′, the circuit board structure of the present invention comprises a core board 3 which has a dielectric layer 34 having a first surface 340 and an opposite second surface 341; at least one high dielectric coefficient material layer 31 formed in the dielectric layer 34 and having one surface at the same height as the second surface 341 of the dielectric layer 34, wherein a first electrode plate 33 is formed on the other surface of the high dielectric coefficient material layer 31; a first circuit layer 372 formed on the first surface 340 of the dielectric layer 34; a second circuit layer 301 formed on the second surface 341 of the dielectric layer 34 and having a second electrode plate 302 corresponding to the first electrode plate 33; and a first conductive via 370 formed in the dielectric layer 34 and electrically connecting the first electrode plate 33 and the first circuit layer 372.

In the above-mentioned structure of the core board 3, the second circuit layer 301 further comprises a conductive wire 303 electrically connecting to the second electrode plate 302. In addition, the core board 3 further comprises at least one second conductive via 371 (shown in FIGS. 2e and 2e′) or at least one conductive through-hole 381 (shown in FIGS. 3e and 3e′) formed in the dielectric layer 34, electrically connectting the first circuit layer 372 and the second circuit layer 301.

Furthermore, as shown in FIGS. 2f, 2f′, 3f, and 3f′, the fabricated structure of the core board 3 having capacitors embedded therein can be added with a built-up structure 4 on each of the opposite two sides, wherein the built-up structure 4 each has at least one dielectric layer 400, at least one circuit layer 401, a plurality of conductive vias 402, a plurality of connecting pads 403, and a solder mask layer 5, having a plurality of openings 50 to expose the connecting pads 403.

Consequently, in the circuit board structure having capacitors embedded therein of the present invention, embedding the capacitors into the core board to thereby avoid the highly circuit-concentrated area so as to increase flexibility of circuit layout on/in the board. Further, fabricating the capacitors in the carrier board followed by forming conductive vias or through-holes in the present invention can reduce the alignment errors.

The aforementioned embodiments are only for example, so that the scope of the present invention is the same as hereinafter claimed, but is not limited to the aforementioned embodiments.

What is claimed is:

1. A circuit board structure having capacitors embedded therein comprising:
a core board having a dielectric layer with a first surface and an opposite second surface;
at least one high dielectric coefficient material layer formed in the dielectric layer and having one surface at the same height as the second surface of the dielectric layer, wherein a first electrode plate is formed on the other surface of the high dielectric coefficient material layer;
a first circuit layer formed on the first surface of the dielectric layer;
a second circuit layer formed on the second surface of the dielectric layer and having a second electrode plate corresponding to the first electrode plate; and
a first conductive via formed in the dielectric layer and electrically connecting the first electrode plate and the first circuit layer.

2. The circuit board structure according to claim 1, wherein the second circuit layer further comprises a conductive wire electrically connecting to the second electrode plate.

3. The circuit board structure according to claim 1, further comprising at least one second conductive via formed in the dielectric layer and electrically connecting the first circuit layer and the second circuit layer.

4. The circuit board structure according to claim 1, further comprising at least one conductive through-hole formed in the dielectric layer and electrically connecting the first circuit layer and the second circuit layer.

5. The circuit board structure according to claim 1, wherein the first electrode plate is made of one of the group consisting of copper, tin, nickel, chromium, titanium, copper-chromium alloy, and tin-lead alloy.

6. The circuit board structure according to claim 1, further comprising a built-up structure formed on each of the two sides of the circuit board, wherein the built-up structure has at least one dielectric layer, at least one circuit layer, a plurality of conductive vias, a plurality of connecting pads, and a solder mask layer having a plurality of openings formed on the surface of the built-up structure to expose the connecting pads.

7. A fabricating method for a circuit board having capacitors embedded therein comprising following steps:
providing a carrier board having at least one high dielectric coefficient material layer formed on a part of one surface of the carrier board, and forming a first electrode plate on the surface of the high dielectric coefficient material layer;
forming a dielectric layer on the surface of the carrier board with the first electrode plate formed thereon;
forming a first via hole corresponding to the first electrode plate in the dielectric layer;
forming a first circuit layer on the first surface of the dielectric layer and a first conductive via in the first via hole; and
forming a second circuit layer on the second surface of the dielectric layer and at least a second electrode plate within the second circuit layer corresponding to the first electrode plate.

8. The fabricating method according to claim 7, wherein the carrier board is made of one of metal and ceramic.

9. The fabricating method according to claim 8, wherein before forming the second circuit layer, as the carrier board is made of metal, the thickness of the carrier board is decreased.

10. The fabricating method according to claim 9, wherein the second circuit layer is carried out by etching.

11. The fabricating method according to claim 7, wherein the first circuit layer is formed by forming a seed layer by electroless plating, forming a metal layer on the seed layer by electro-plating, and then carrying out the first circuit layer by etching the metal layer.

12. The fabricating method according to claim 8, wherein the carrier board is removed to expose the second surface of the dielectric layer before forming the second circuit layer.

13. The fabricating method according to claim 12, wherein the first circuit layer and the second circuit layer are formed by forming a seed layer by electroless plating, forming a patterned resistive layer on the seed layer, and then carrying out the circuit layers by electroplating through the seed layer.

14. The fabricating method according to claim 7, wherein the second circuit layer further comprises a conductive wire electrically connecting to the second electrode plate.

15. The fabricating method according to claim 7, wherein an thickness-increasing layer is formed by one way of physical deposition and chemical deposition, to thereby serve as the first electrode plate.

16. The fabricating method according to claim 15, further comprising forming an pre-electrode layer by one way of sputtering, coating, and printing on the surface of the high dielectric coefficient material layer, before forming the first electrode plate.

17. The fabricating method according to claim 7, wherein the first conductive via electrically connects the first circuit layer and the first electrode plate.

18. The fabricating method according to claim 7, further comprising forming at least one second conductive via in the dielectric layer, wherein the second conductive via electrically connects the first circuit layer and the second circuit layer.

19. The fabricating method according to claim 7, further comprising forming at least one conductive through-hole in the dielectric layer, wherein the conductive through-hole electrically connects the first circuit layer and the second circuit layer.

20. The fabricating method according to claim 7, further comprising forming a built-up structure on each of the two sides of the circuit board, wherein the built-up structure has at least one dielectric layer, at least one circuit layer, a plurality of conductive vias, a plurality of connecting pads, and a solder mask layer having a plurality of openings formed on the surface of the built-up structure to expose the connecting pads.
